(19) United States
(12) Patent Application Publication
(10) Pub. No.: US 2006/0049414 A1
(43) Pub. Date: Mar. 9, 2006

(54) Novel oxynitride phosphors

(76) Inventors: Ramachandran Gopi Chandran, Bangalore (IN); Dan Hancu, Clifton Park, NY (US); Nadagouda Mallikarjuna, Richardson, TX (US); Emil Vergilov Radkov, Euclid, OH (US); Anant Achyut Setlur, Niskayuna, NY (US); Venkatraman Sivaramakrishan, Bangalore (IN); Alok Mani Srivastava, Niskayuna, NY (US); Madras Venugopal Shankar, Bangalore (IN)

Correspondence Address: Scott A. McCollister, Esq.;Fay, Sharpe, Fagan, Minnich & McKee, LLP, Seventh Floor, 1100 Superior Avenue, Cleveland, OH, 44114-2579, US

(21) Appl. No.: 11/207,489

(22) Filed: Aug. 19, 2005

Related U.S. Application Data
(60) Provisional application No. 60/602,808, filed on Aug. 19, 2004.
(60) Provisional application No. 60/609,859, filed on Sep. 14, 2004.
(60) Provisional application No. 60/643,274, filed on Jan. 12, 2005.

(51) Int. Cl. H01L 33/00

(52) U.S. Cl. 257/89

(57) ABSTRACT

Disclosed are oxynitride and oxide phosphor compositions having various formulations. Also disclosed are phosphor blends of the above phosphors and one or more additional phosphors and light emitting devices incorporating the same. The phosphors and their blends can be used in saturated color light sources (e.g. traffic signals), as well as white light sources for general illumination purposes.

This application claims priority from, and the benefit of the filing date of, U.S. Provisional Patent Application Ser. Nos. 60/602,808, filed on Aug. 19, 2004; 60/609,859, filed on Sep. 14, 2004; and 60/643,274, filed on Jan. 12, 2005.

### BACKGROUND

The present exemplary embodiments relate to novel phosphor compositions. They find particular application in conjunction with converting LED-generated ultraviolet (UV), violet or blue radiation into white light or other colored light for general illumination purposes. It should be appreciated, however, that the invention is also applicable to the conversion of radiation from UV, violet and/or blue lasers as well as other white or colored light sources for different applications.

Light emitting diodes (LEDs) are semiconductor light emitters often used as a replacement for other light sources, such as incandescent lamps. They are particularly useful as display lights, warning lights and indicating lights or in other applications where colored light is desired. The color of light produced by an LED is dependent on the type of semiconductor material used in its manufacture.

Colored semiconductor light emitting devices, including light emitting diodes and lasers (both are generally referred to herein as LEDs), have been produced from Group III-V alloys such as gallium nitride (GaN). To form the LEDs, layers of the alloys are typically deposited epitaxially on a substrate, such as silicon carbide or sapphire, and may be doped with a variety of n and p type dopants to improve properties, such as light emission efficiency. With reference to the GaN-based LEDs, light is generally emitted in the UV and/or blue range of the electromagnetic spectrum. Until quite recently, LEDs have not been suitable for lighting uses where a bright white light is needed, due to the inherent color of the light produced by the LED.

Recently, techniques have been developed for converting the light emitted from LEDs to useful light for illumination purposes. In one technique, the LED is coated or covered with a phosphor layer. A phosphor is a luminescent material that absorbs radiation energy in a portion of the electromagnetic spectrum and emits energy in another portion of the electromagnetic spectrum. Phosphors of one important class are crystalline inorganic compounds of very high chemical purity and of controlled composition to which small quantities of other elements (called “activators”) have been added to convert them into efficient fluorescent materials. With the right combination of activators and host inorganic compounds, the color of the emission can be controlled. Most useful and well-known phosphors emit radiation in the visible portion of the electromagnetic spectrum in response to excitation by electromagnetic radiation outside the visible range.

By interposing a phosphor excited by the radiation generated by the LED, light of a different wavelength, e.g., in the visible range of the spectrum, may be generated. Colored LEDs are often used in toys, indicator lights and other devices. Manufacturers are continuously looking for new colored phosphors for use in such LEDs to produce custom colors and higher luminosity.

In addition to colored LEDs, a combination of LED generated light and phosphor generated light may be used to produce white light. The most popular white LEDs are based on blue emitting GaInN chips. The blue emitting chips are coated with a phosphor that converts some of the blue radiation to a complementary color, e.g. a yellow-green emission. The total of the light from the phosphor and the LED chip provides a color point with corresponding color coordinates (x and y) and correlated color temperature (CCT), and its spectral distribution provides a color rendering capability, measured by the color rendering index (CRI).

The CRI is commonly defined as a mean value for 8 standard color samples (R₁₋₈), usually referred to as the General Color Rendering Index and abbreviated as Rₐ, although 14 standard color samples are specified internationally and one can calculate a broader CRI (R₁₋₁₄) as their mean value. In particular, the R₉ value, measuring the color rendering for the strong red, is very important for a range of applications, especially of medical nature.

One known white light emitting device comprises a blue light-emitting LED having a peak emission wavelength in the blue range (from about 440 nm to about 480 nm) combined with a phosphor, such as cerium doped yttrium aluminum garnet Y₃Al₅O₁₂:Ce³⁺ (“YAG”). The phosphor absorbs a portion of the radiation emitted from the LED and converts the absorbed radiation to a yellow-green light. The remainder of the blue light emitted by the LED is transmitted through the phosphor and is mixed with the yellow light emitted by the phosphor. A viewer perceives the mixture of blue and yellow light as a white light.

The blue LED-YAG phosphor device described above typically produces a white light with a general color rendering index (Rₐ) of from about 70-82 with a tunable color temperature range of from about 4000K to 8000K. Recent commercially available LEDs using a blend of YAG phosphor and a red phosphor (CaS:Eu²⁺) provide color temperatures below 4000K with a Rₐ around 90. While such LEDs are suitable for some applications, many users desire a light source with an even higher Rₐ, one similar to that of incandescent lamps with a value of 95-100.

Due to their increasing use, there is a continued demand for additional phosphor compositions that can be used in the manufacture of both white and colored LEDs. Such phosphor compositions will allow an even wider array of LEDs with desirable properties.

### BRIEF DESCRIPTION

In a first aspect, there is provided a light emitting device including a semiconductor light source having a peak emission from about 250 to about 550 nm and a phosphor material radiationally coupled to the light source, the phosphor material comprising at least one of:
a) M₄₊ₓLn₇₋ₓ(Si,Ge)_{12-y}(Al,Ga)_{y}N_{23-x-y}O_{1+x+y}[BN₃]:Ce³⁺,Eu³⁺,Bi³⁺,Tb³⁺,Eu²⁺,Mn²⁺where 0≦x≦7, 0≦y≦12; M is at least one of Mg, Ca, Sr, Ba, or Zn and Ln is at least one of the rare earth elements, Sc, Y, Bi, or Sb;
b) Ln₃₋ₓMₓ(Si,Ge)₈N₁₁₋ₓO₄₊ₓ:RE; Ln₃(Si,Ge)₈₋ₓ(Al,Ga),N₁₁₋ₓO₄₊ₓ:RE; or Ln₃₋ₓMₓ(Si,Ge)₈₋ₓAlₓN_{11-x/2}O_{4-x/4}:RE where Ln is at least one of Lu, Y, La, Gd, or Sc, M is at least one of Ca, Sr, Ba or Zn, 0≦x≦3, and RE is at least one of Ce³⁺, Tb³⁺, Pr3+, Dy³⁺, Sm³⁺, Eu³⁺, Eu²⁺, Mn²⁺, or Bi³⁺;
c) Ln₄Si₂O₇N₂:RE where Ln is at least one of Lu, Y, La, Gd, or Sc and RE is at least one of Ce³⁺, Tb³⁺, Pr³⁺, Dy³⁺, Eu³⁺, Sm³⁺, Eu³⁺, Eu²⁺, Mn²⁺, or Bi³⁺;
d) Ln₄₋ₓMₓ(Si,Ge)₂N₂₋ₓO₇₊ₓ or Ln₄₋ₓMₓ(Si,Ge)_{2-y}(Al,Ga)_{y}N_{2-x-y}O_{7+x+y}:RE where Ln is at least one of Lu, Y, La, Gd, or Sc, M is at least one of Ca, Sr, Ba, or Zn, 0≦x≦2, 0≦y≦2 , and RE is at least one of Ce³⁺, Tb³⁺, Pr³⁺, Dy³⁺, Sm³⁺, Eu³⁺, Eu²⁺, Mn²⁺, or Bi³⁺;
e) MBNO:Eu²⁺,Mn²⁺ where M is at least one of Mg, Ca, Ba, Sr, or Zn; or
f) M_{0.755-x}Lnₓ(Al,Ga)_{1.71}(Si,Ge)_{2.29}O₈₋ₓNₓ:Ce³⁺,Eu³⁺,Bi^{3 +},Tb³⁺,Eu²⁺, Mn²⁺, where 0≦x≦0.755; M_{0.755}(Al,Ga)_{1.71-x}(Si,Ge)_{2.29+x}O₈₋ₓNₓ:Ce³⁺,Eu³⁺,Bi³⁺,Tb³⁺,Eu²⁺,Mn²⁺ where 0≦x≦1.71; M₁₋ₓLnₓ(Al,Ga)₂(Si,Ge)₂O₈₋ₓNₓ:Ce³⁺,Eu³⁺,Bi³⁺,Tb³⁺,Eu²⁺,Mn²⁺, where 0≦x≦1; or M(Al,Ga)₂₋ₓ(Si,Ge)₂₊ₓO₈₋ₓNₓ:Ce³⁺,Eu³⁺,Bi³⁺,Tb³⁺,Eu²⁺,Mn²⁺, where 0≦x≦2, and wherein for any of the preceding M is at least one of Mg, Ca, Ba, or Zn and Ln is at least one of La, Y, Gd, Lu, Pr, Nd or Sm.

In a second aspect, there is provided a phosphor composition having the formula:
a) M₄₊ₓLn₇₋ₓ(Si,Ge)_{12-y}(Al,Ga)_{y}N_{23-x-y}O_{1+x+y}[BN₃]:Ce³⁺,EU³⁺,Bi³⁺,Tb³⁺,Eu²⁺,Mn²⁺ where 0≦x≦7, 0≦y≦12; M is at least one of Mg, Ca, Sr, Ba, or Zn and Ln is at least one of the rare earth elements, Sc, Y, Bi, or Sb;

b) Ln₃₋ₓMₓ(Si,Ge)₈N₁₁₋ₓO₄₊ₓ:RE; Ln₃(Si,Ge)₈₋ₓ(Al,Ga)ₓN₁₁₋ₓ,O₄₊:RE; or Ln₃₋ₓMₓ(Si,Ge)₈₋ₓAlₓN_{11-x/2}O_{4-x/4}:RE where Ln is at least one of Lu, Y, La, Gd, or Sc, M is at least one of Ca, Sr, Ba or Zn, 0≦x≦3, and RE is at least one of Ce³⁺, Tb³⁺, Pr³⁺, Dy³⁺, Sm³⁺, Eu³⁺, Eu²⁺, Mn²⁺, or Bi³⁺;
c) Ln₄Si₂O₇N₂:RE where Ln is at least one of Lu, Y, La, Gd, or Sc and RE is at least one of Ce³⁺, Tb³⁺, Pr³⁺, Dy³⁺, Eu³⁺, Sm³⁺, Eu³⁺, Eu²⁺, Mn²⁺, or Bi³⁺;

d) Ln₄₋ₓMₓ(Si,Ge)₂N₂₋ₓO₇₊ₓ or Ln₄₋ₓMₓ(Si,Ge)_{2-y}(Al,Ga)_{y}N_{2-x-y}O_{7+x+y}:RE where Ln is at least one of Lu, Y, La, Gd, or Sc, M is at least one of Ca, Sr, Ba, or Zn, 0≦x≦2, 0≦y≦2, and RE is at least one of Ce³⁺, Tb³⁺, Pr³⁺, Dy³⁺, Sm³⁺, Eu³⁺, Eu²⁺, Mn²⁺, or Bi³⁺;

e) MBNO:Eu²⁺,Mn²⁺ where M is at least one of Mg, Ca, Ba, Sr, or Zn; or
f) M_{0.755-x}Lnₓ(Al,Ga)_{1.71}(Si,Ge)_{2.29}O₈₋ₓNₓ:Ce³⁺,Eu³⁺,Bi³⁺,Tb³⁺,Eu²⁺,Mn²⁺, where 0≦x≦0.755; M_{0.755}(Al,Ga)_{1.71-x}(Si,Ge)_{2.29+x}O₈₋ₓNₓ:Ce³⁺,Eu³⁺,Bi³⁺,Tb³⁺,Eu²⁺,Mn²⁺ where 0≦x≦1.71; M₁₋ₓLnₓ(Al,Ga)₂(Si,Ge)₂O₈₋ₓNₓ:Ce³⁺,Eu³⁺,Bi³⁺,Tb³⁺,Eu²⁺,Mn²⁺, where 0≦x≦1; or M(Al,Ga)₂₋ₓ(Si,Ge)₂₊ₓO₈₋ₓNₓ:Ce³⁺,Eu³⁺,Bi³⁺,Tb³⁺,Eu²⁺,Mn²⁺, where 0≦x≦2, and wherein for any of the preceding M is at least one of Mg, Ca, Ba, or Zn and Ln is at least one of La, Y, Gd, Lu, Pr, Nd or Sm.

In a third aspect, there is provided a phosphor blend including a first phosphor having the formula:
a) M₄₊ₓLn₇₋ₓ(Si,Ge)_{12-y}(Al,Ga)_{y}N_{23-x-y}O_{1+x+y}[BN₃:Ce³⁺,Eu³⁺,Bi³⁺,Tb³⁺,Eu²⁺,Mn²⁺ where 0≦x≦7, 0≦y≦12; M is at least one of Mg, Ca, Sr, Ba, or Zn and Ln is at least one of the rare earth elements, Sc, Y, Bi, or Sb;
b) Ln₃₋ₓMₓ(Si,Ge)₈N₁₁₋ₓO₄₊ₓ:RE; Ln₃(Si,Ge)₈₋ₓ(Al,Ga),ₓN₁₁₋ₓO₄₊ₓ:RE; or Ln₃₋ₓMₓ(Si,Ge)₈₋ₓAlₓN_{11-x/2}O_{4-x/4}:RE where Ln is at least one of Lu, Y, La, Gd, or Sc, M is at least one of Ca, Sr, Ba or Zn, 0≦x≦3, and RE is at least one of Ce³⁺, Tb³⁺, Pr³⁺, Dy³⁺, Sm³⁺, Eu³⁺, Eu²⁺, Mn²⁺, or Bi³⁺;

c) Ln₄Si₂O₇N₂:RE where Ln is at least one of Lu, Y, La, Gd, or Sc and RE is at least one of Ce³⁺, Tb³⁺, Pr³⁺, Dy³⁺, Eu³⁺, Sm³⁺, Eu³⁺, Eu²⁺, Mn²⁺, or Bi³⁺;
d) Ln₄₋ₓMₓ(Si,Ge)₂N₂₋ₓO₇₊ₓ or Ln₄₋ₓMₓ(Si,Ge)_{2-y}(Al,Ga)_{y}N_{2-x-y}O_{7+x+y}:RE where Ln is at least one of Lu, Y, La, Gd, or Sc, M is at least one of Ca, Sr, Ba, or Zn, 0≦x≦2, 0≦y≦2 , and RE is at least one of Ce³⁺, Tb³⁺, Pr³⁺, Dy³⁺, Sm³⁺, Eu³⁺, Eu²⁺, Mn²⁺, or Bi³⁺;
e) MBNO:Eu²⁺, Mn²⁺ where M is at least one of Mg, Ca, Ba, Sr, or Zn; or
f) M_{0.755-x}Lnₓ(Al,Ga)_{1.71}(Si,Ge)_{2.29}O₈₋ₓNₓ:Ce³⁺,Eu³⁺,Bi³⁺,Tb³⁺,Eu²⁺, Mn²⁺, where 0≦x≦0.755; M_{0.755}(Al,Ga)_{1.71-x}(Si,Ge)_{2.29+x}O₈₋ₓNₓ:Ce³⁺,Eu³⁺,Bi³⁺,Tb³⁺,Eu²⁺,Mn²⁺ where 0≦x≦1.71; M₁₋ₓLnₓ(Al,Ga)₂(Si,Ge)₂O₈₋ₓNₓ:Ce³⁺,Eu³⁺,Bi³⁺,Tb³⁺,Eu²⁺,Mn²⁺, where 0≦x≦1; or M(Al,Ga)₂₋ₓ(Si,Ge)₂₊O₈₋ₓNₓ:Ce³⁺,Eu³⁺,Bi³⁺,Tb³⁺,Eu²⁺,Mn²⁺, where 0≦x≦2, and wherein for any of the preceding M is at least one of Mg, Ca, Ba, or Zn and Ln is at least one of La, Y, Gd, Lu, Pr, Nd or Sm.

### BRIEF DESCRIPTION OF THE DRAWINGS

FIG. 1 is a schematic cross-sectional view of an illumination system in accordance with one embodiment of the present invention.

FIG. 2 is a schematic cross-sectional view of an illumination system in accordance with a second embodiment of the present invention.

FIG. 3 is a schematic cross-sectional view of an illumination system in accordance with a third embodiment of the present invention.

FIG. 4 is a cutaway side perspective view of an illumination system in accordance with a fourth embodiment of the present invention.

FIG. 5 is the emission spectrum under 405 nm excitation of Sr_{10.79}Eu_{0.21}Si₉Al₃N₁₃O₁₁[BN₃].

FIG. 6 is the excitation spectrum of Sr_{10.79}Eu_{0.21}Si₉Al₃N₁₃O₁₁[BN₃].

FIG. 7 is the emission spectrum under 405 nm excitation of Ba₄Sr_{6.79}Eu_{0.21}Si₉Al₃N₁₃O₁₁[BN₃].

FIG. 8 is the excitation spectrum of Ba₄Sr_{6.79}Eu_{0.21}Si₉Al₃N₁₃O₁₁[BN₃].

FIG. 9 is the emission spectrum under 405 nm excitation of Sr_{0.95}Eu_{0.05}BNO.

FIG. 10 is the excitation spectrum of Sr_{0.95}Eu_{0.05}BNO.

### DETAILED DESCRIPTION

Phosphors convert radiation (energy) to visible light. Different combinations of phosphors provide different colored light emissions. The colored light that originates from the phosphors provides a color temperature. Novel phosphor compositions are presented herein as well as their use in LED and other light sources.

A phosphor conversion material (phosphor material) converts generated UV or blue radiation to a different wavelength visible light. The color of the generated visible light is dependent on the particular components of the phosphor material. The phosphor material may include only a single phosphor composition or two or more phosphors of basic color, for example a particular mix with one or more of a yellow and red phosphor to emit a desired color (tint) of light. As used herein, the terms “phosphor” and “phosphor material” may be used to denote both a single phosphor composition as well as a blend of two or more phosphor compositions.

It was determined that an LED lamp that produces a white or colored light would be useful to impart desirable qualities to LEDs as light sources. Therefore, in one embodiment of the invention, a phosphor coated LED chip is disclosed for providing white or colored light. The phosphor material may be an individual phosphor or a phosphor blend of two or more phosphor compositions, including individual phosphors that convert radiation at a specified wavelength, for example radiation from about 250 to 550 nm as emitted by a UV to visible LED, into a different wavelength visible light. The visible light provided by the phosphor material (and LED chip if emitting visible light) comprises a bright white or colored light with high intensity and brightness.

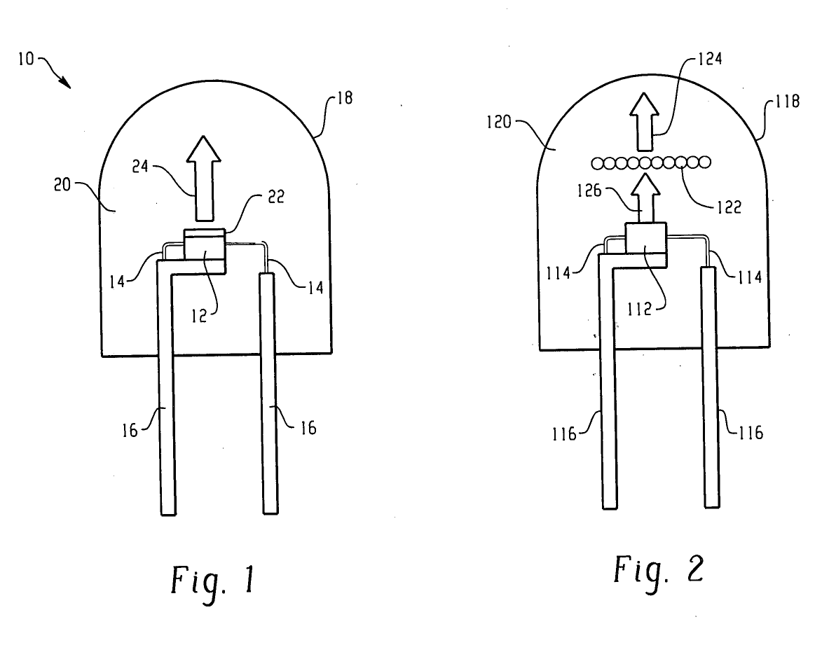

With reference to FIG. 1, an exemplary LED based light emitting assembly or lamp 10 is shown in accordance with one preferred structure of the present invention. The light emitting assembly 10 comprises a semiconductor UV or visible radiation source, such as a light emitting diode (LED) chip 12 and leads 14 electrically attached to the LED chip. The leads 14 may comprise thin wires supported by a thicker lead frame(s) 16 or the leads may comprise self supported electrodes and the lead frame may be omitted. The leads 14 provide current to the LED chip 12 and thus cause the LED chip 12 to emit radiation.

The lamp may include any semiconductor visible or UV light source that is capable of producing white light when its emitted radiation is directed onto the phosphor. The preferred peak emission of the LED chip in the present invention will depend on the identity of the phosphors in the disclosed embodiments and may range from, e.g., 250-550 nm. In one preferred embodiment, however, the emission of the LED will be in the near UV to deep blue region and have a peak wavelength in the range from about 350 to about 430 nm. Typically then, the semiconductor light source comprises an LED doped with various impurities. Thus, the LED may comprise a semiconductor diode based on any suitable III-V, II-VI or IV-IV semiconductor layers and having an emission wavelength of about 250 to 550 nm.

Preferably, the LED may contain at least one semiconductor layer comprising GaN, ZnO or SiC. For example, the LED may comprise a nitride compound semiconductor represented by the formula InᵢGaⱼAlₖN (where 0≦i; 0≦j; 0≦k and i+j+k=1) having a peak emission wavelength greater than about 200 nm and less than about 500 nm. Such LED semiconductors are known in the art. The radiation source is described herein as an LED for convenience. However, as used herein, the term is meant to encompass all semiconductor radiation sources including, e.g., semiconductor laser diodes.

Although the general discussion of the exemplary structures of the invention discussed herein are directed toward inorganic LED based light sources, it should be understood that the LED chip may be replaced by an organic light emissive structure or other radiation source unless otherwise noted and that any reference to LED chip or semiconductor is merely representative of any appropriate radiation source.

The LED chip 12 may be encapsulated within a shell 18, which encloses the LED chip and an encapsulant material 20. The shell 18 may be, for example, glass or plastic. Preferably, the LED 12 is substantially centered in the encapsulant 20. The encapsulant 20 is preferably an epoxy, plastic, low temperature glass, polymer, thermoplastic, thermoset material, resin or other type of LED encapsulating material as is known in the art. Optionally, the encapsulant 20 is a spin-on glass or some other high index of refraction material. In one embodiment, the encapsulant material 20 is a polymer material, such as epoxy, silicone, or silicone epoxy, although other organic or inorganic encapsulants may be used. Both the shell 18 and the encapsulant 20 are preferably transparent or substantially optically transmissive with respect to the wavelength of light produced by the LED chip 12 and a phosphor material 22 (described below). In an alternate embodiment, the lamp 10 may only comprise an encapsulant material without an outer shell 18. The LED chip 12 may be supported, for example, by the lead frame 16, by the self supporting electrodes, the bottom of the shell 18, or by a pedestal (not shown) mounted to the shell or to the lead frame.

The structure of the illumination system includes a phosphor material 22 radiationally coupled to the LED chip 12. Radiationally coupled means that the elements are associated with each other so that at least part of the radiation emitted from one is transmitted to the other.

This phosphor material 22 is deposited on the LED 12 by any appropriate method. For example, a water-based suspension of the phosphor(s) can be formed, and applied as a phosphor layer to the LED surface. In one such method, a silicone, epoxy or other matrix material is used to create a slurry in which the phosphor particles are randomly suspended and placed around the LED. This method is merely exemplary of possible positions of the phosphor material 22 and LED 12. Thus, the phosphor material 22 may be coated over or directly on the light emitting surface of the LED chip 12 by coating and drying the phosphor suspension over the LED chip 12. Both the shell 18 and the encapsulant 20 should be transparent to allow light 24 to be transmitted through those elements. Although not intended to be limiting, in one embodiment, the median particle size of the phosphor material may be from about 1 to about 10 microns.

FIG. 2 illustrates a second preferred structure of the system according to the preferred aspect of the present invention. The structure of the embodiment of FIG. 2 is similar to that of FIG. 1, except that the phosphor material 122 is interspersed within the encapsulant material 120, instead of being formed directly on the LED chip 112. The phosphor material (in the form of a powder) may be interspersed within a single region of the encapsulant material 120 or, more preferably, throughout the entire volume of the encapsulant material. Radiation 126 emitted by the LED chip 112 mixes with the light emitted by the phosphor material 122, and the mixed light appears as white light 124. If the phosphor is to be interspersed within the encapsulant material 120, then a phosphor powder may be added to a polymer precursor, loaded around the LED chip 112, and then the polymer precursor may be cured to solidify the polymer material. Other known phosphor interspersion methods may also be used, such as transfer loading.

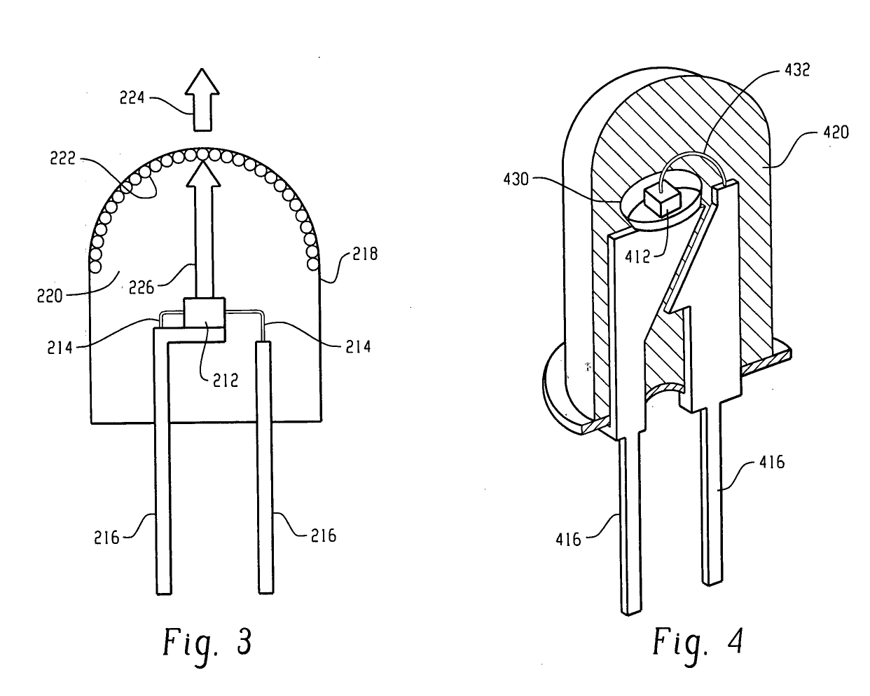

FIG. 3 illustrates a third preferred structure of the system according to the preferred aspects of the present invention. The structure of the embodiment shown in FIG. 3 is similar to that of FIG. 1, except that the phosphor material 222 is coated onto a surface of the shell 218, instead of being formed over the LED chip 212. The phosphor material is preferably coated on the inside surface of the shell 218, although the phosphor may be coated on the outside surface of the shell, if desired. The phosphor material 222 may be coated on the entire surface of the shell or only a top portion of the surface of the shell. The radiation 226 emitted by the LED chip 212 mixes with the light emitted by the phosphor material 222, and the mixed light appears as white light 224. Of course, the structures of FIGS. 1-3 may be combined and the phosphor may be located in any two or all three locations or in any other suitable location, such as separately from the shell or integrated into the LED.

In any of the above structures, the lamp 10 may also include a plurality of scattering particles (not shown), which are embedded in the encapsulant material. The scattering particles may comprise, for example, Al₂O₃ particles such as alumina powder or TiO₂ particles. The scattering particles effectively scatter the coherent light emitted from the LED chip, preferably with a negligible amount of absorption.

As shown in a fourth preferred structure in FIG. 4, the LED chip 412 may be mounted in a reflective cup 430. The cup 430 may be made from or coated with a reflective material, such as alumina, titania, or other dielectric powder known in the art. A preferred reflective material is Al₂O₃. The remainder of the structure of the embodiment of FIG. 4 is the same as that of any of the previous Figures, and includes two leads 416, a conducting wire 432 electrically connecting the LED chip 412 with the second lead, and an encapsulant material 420.

In one embodiment, there is provided a novel phosphor composition, which may be used in the phosphor material 22 in the above described LED light, wherein the composition is a phosphor having the formula M₄₊ₓLn₇₋ₓ(Si,Ge)_{12-y}(Al,Ga)_{y}N_{23-x-y}O_{1+x+y}[BN₃]:Ce³⁺,Eu³⁺,Bi³⁺,Tb³⁺,Eu²⁺,Mn²⁺ where 0≦x≦7, 0≦y≦12; M is at least one of Mg, Ca, Sr, Ba, or Zn and Ln is at least one of the rare earth elements, Sc, Y, Bi, or Sb.

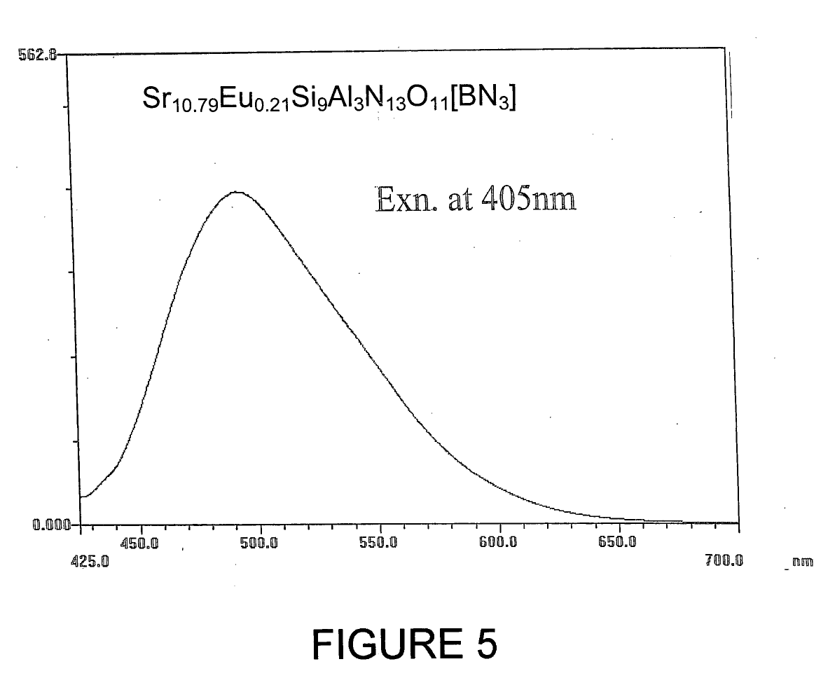

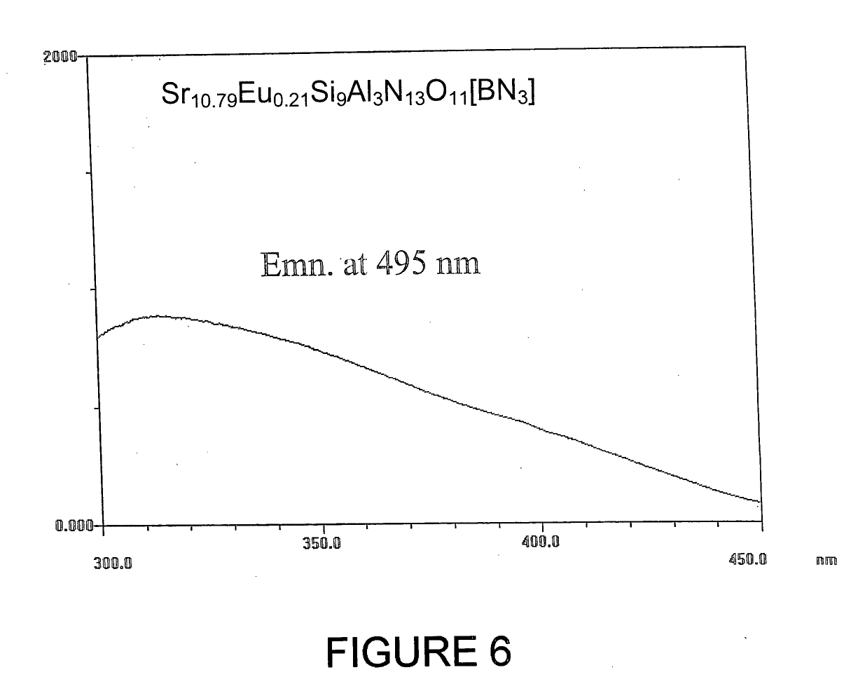

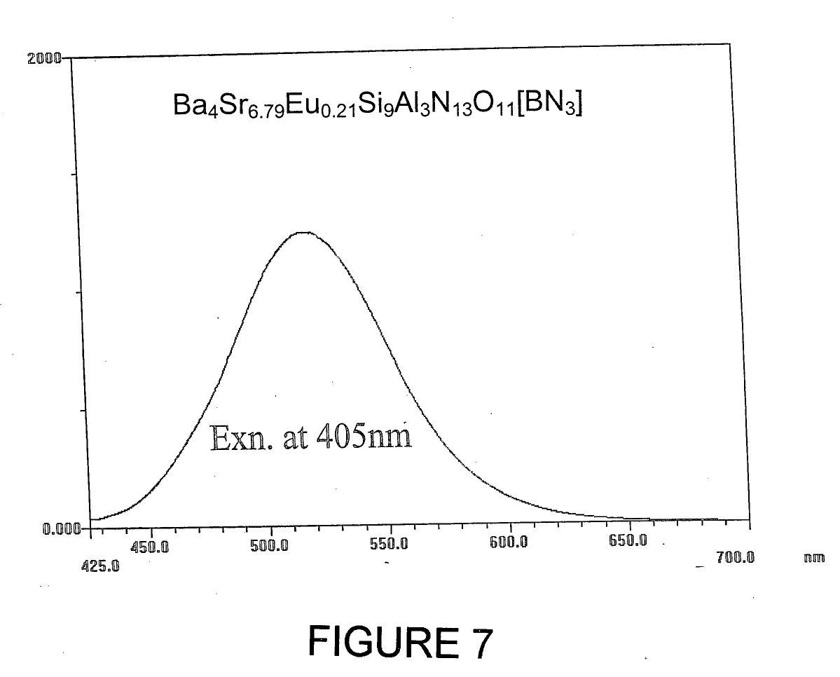

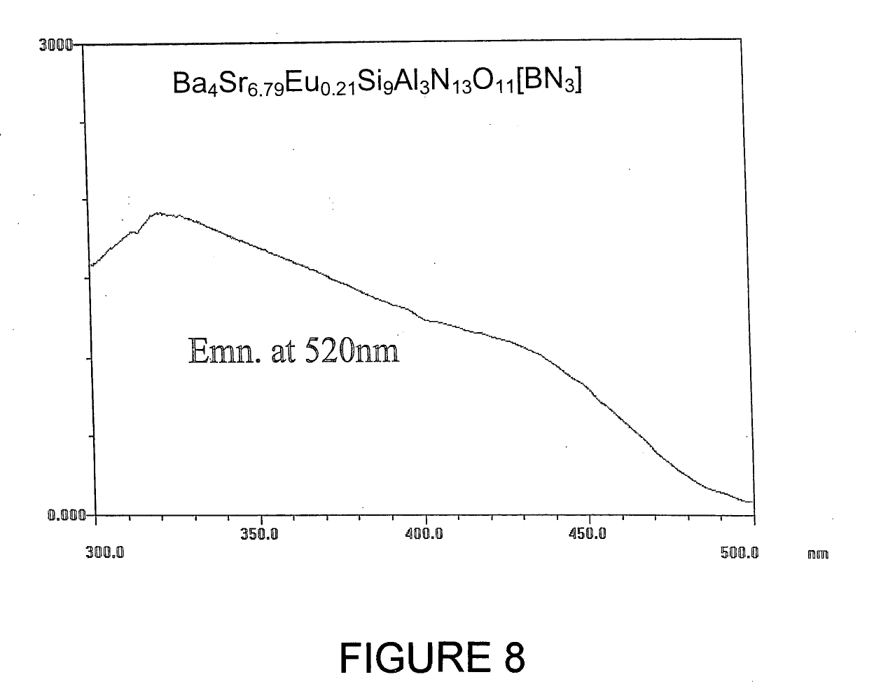

Specific exemplary phosphors according to the above embodiment include Sr_{10.79}Eu_{0.21}Si₉Al₃N₁₃O₁₁[BN₃] which has a maximum peak emission under 405 nm excitation at about 490 nm, and Ba₄Sr_{6.79}Eu_{0.21}Si₉Al₃N₁₃O₁₁[BN₃], which has a maximum peak emission under 405 nm excitation at about 520 nm. The emission and excitation spectrum of Sr_{10.79}Eu_{0.21}Si₉Al₃N₁₃O₁₁[BN₃] is shown in FIGS. 5 and 6, respectively. Likewise, the emission and excitation spectrum of Ba₄Sr_{6.79}Eu_{0.21}Si₉Al₃N₁₃O₁₁[BN₃] is shown in FIGS. 7 and 8, respectively. These phosphors may also be used in green traffic lights.

In a second embodiment, the composition is a rare earth oxynitride phosphor composition having a formula selected from Ln₃₋ₓMₓ(Si,Ge)₈N₁₁₋ₓO₄₊ₓ:RE; Ln₃(Si,Ge)₈₋ₓ(Al,Ga)ₓN₁₁₋ₓO₄₊ₓ:RE; or Ln₃₋ₓMₓ(Si,Ge)₈₋ₓAlₓN_{11-x/2}O_{4-x/4}:RE where Ln is at least one of Lu, Y, La, Gd, or Sc, M is at least one of Ca, Sr, Ba or Zn, 0≦x≦3, and RE is at least one of Ce³⁺, Tb³⁺, Pr³⁺, Dy³⁺, Sm³⁺, Eu³⁺, Eu²⁺, Mn²⁺, or Bi³⁺.

Trivalent RE activators can be substituted at the Ln site (up to 20 mole %) while the divalent activators (Eu²⁺ and/or Mn²⁺) can be substituted at the M site (up to 20 mole %). Both trivalent and divalent activator substitutions can be individually or simultaneously done. Since energy transfer occurs between these two ions, one can control the composition of new phosphors for color, absorption and efficiency in LED packages. Preferred phosphors in this embodiment include (La,Y,Gd,Lu)₃Si₈N₁₁O₄:RE, La_{1.8}Ce_{0.2}SrSi₈N₁₀O₅, La₂Sr_{0.9}Eu_{0.1}Si₈N₁₀O₅, La_{0.9}Ce_{0.1}Sr₂Si₆Al₂N₁₀O_{3.5}, and La_{1.9}Ce_{0.1}Sr_{0.9}Eu_{0.1}Si₈N₁₀O₅.

In a third embodiment, there is provided a rare earth oxynitride phosphor composition having a formula Ln₄Si₂O₇N₂:RE where Ln is at least one of Lu, Y, La, Gd, Sc and RE is at least one of Ce³⁺, Tb³⁺, Pr³⁺, Dy³⁺, Eu³⁺, Sm³⁺, Eu³⁺, Eu²⁺, Mn²⁺, and Bi³⁺.

In a fourth embodiment, there is provided a rare earth oxynitride phosphor composition having a formula selected from Ln₄₋ₓMₓ(Si,Ge)₂N₂₋ₓO₇₊ₓ, and Ln₄₋ₓMₓ(Si,Ge)_{2-y}(Al,Ga)_{y}N_{2-x-y}O_{7+x+y}:RE where Ln is at least one of Lu, Y, La, Gd, Sc, M is at least one of Ca, Sr, Ba, and Zn, 0≦x≦2, 0≦y≦2 , and RE is at least one of the Ce³⁺, Tb³⁺, Pr³⁺, Dy³⁺, Sm³⁺, Eu³⁺, Eu²⁺, Mn²⁺, and Bi³⁺.

Exemplary phosphors in this embodiment include (Lu_{0.97}Ce_{0.03})₄Si₂N₂O₇; (Lu_{0.985}Ce_{0.015})₈Si₃AlN₅O₁₂; (Lu_{0.985}Ce_{0.015})₇CaSi₃AlN₄O₁₃; (Lu_{0.985}Ce_{0.015})₆Ca₂Si₃AlN₅O₁₁; (Lu_{0.95}Ce_{0.05})₈Si₂AlN₅O₁₂; (Lu_{0.97}Ce_{0.03})₄Si₄N₄O₈; (Lu_{0.97}Ce_{0.03})₄Si₃AlN₅O₆; (Lu_{0.97}Ce_{0.03})₆Si₃N₄O₉; and (Lu_{0.985}Ce_{0.015})₇CaSi₃AlN₅O_{11.5}

The use of Eu²⁺ along with a trivalent ion is based on the trivalent activator acting as a “sensitizer”, absorbing the radiation emitted by the LED. After absorption, energy is transferred from the RE³⁺ ions to Eu2+ ions, which then release the energy by emitting in the visible region. Since the absorption/emission transitions for RE³⁺ and Eu²⁺ are parity allowed transitions, energy transfer should readily and efficiently occur, even at low concentration of either ion.

With proper composition/synthesis control, one can control the overall phosphor color by adjusting the RE³⁺/Eu²⁺ emission intensity ratio. In addition, the overall concentration of Eu²⁺ in the host lattice can be reduced compared to conventional Eu²⁺ only doped phosphors (such as CaS:Eu²⁺) since RE³⁺ will also absorb LED radiation. Because Eu²⁺ doped phosphors are known to absorb the radiation emitted by other phosphors present in the device, this has the additional benefit of increasing the device package efficiency when additional phosphors are present (such as YAG:Ce), since less of the light emitted by these phosphors will be absorbed due to the lower concentration of Eu²⁺. In one embodiment, the RE³⁺ doping levels may range from about 0.01 to about 20 mol % replacement and the Eu²⁺ doping levels may range from about 0.01 to about 20 mol %.

By altering the identity of activators as well as the identity of Ln and M, one can control the composition of new phosphors for color, absorption and efficiency in LED packages. For example, the presence of Ba in the above second composition gave a 30 nm red shift and is indicative of the spectral tenability of the phosphor composition.

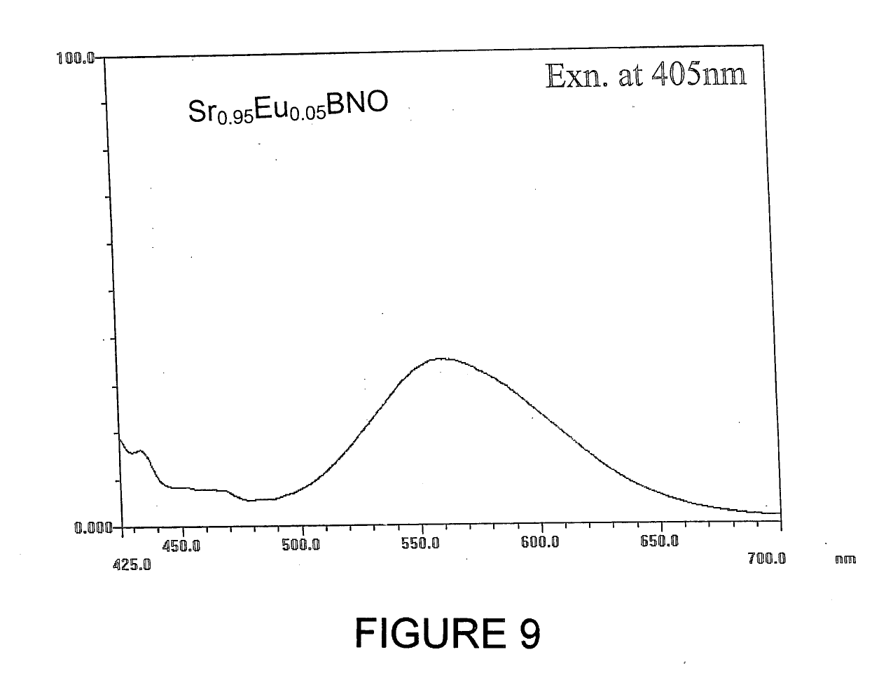

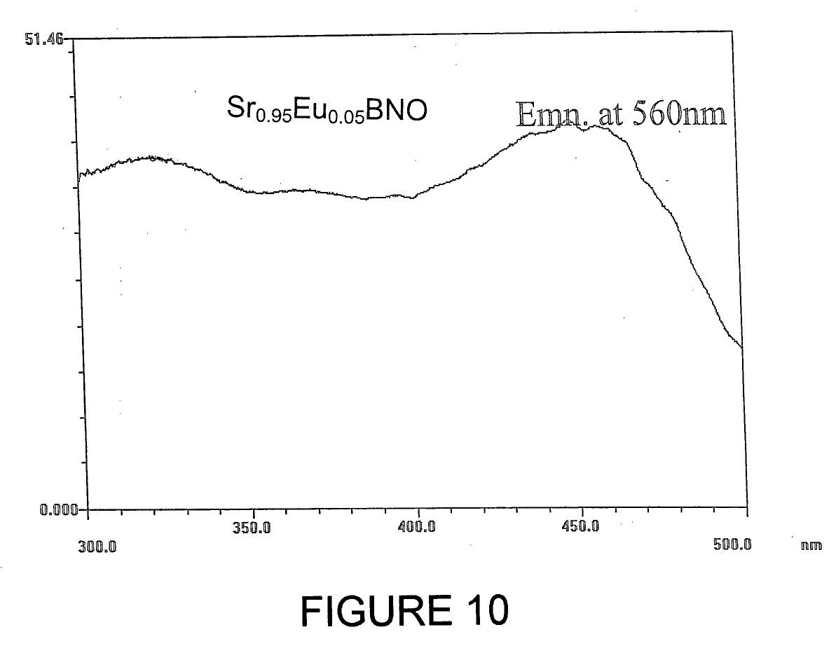

Another specific exemplary phosphor according to the above embodiment is Sr_{0.095}Eu_{0.05}BNO, which has a maximum peak emission under 405 nm excitation at about 560 nm. FIG. 9 is the emission spectrum under 405 nm excitation of Sr_{0.95}Eu_{0.05}BNO. FIG. 10 is the excitation spectrum of Sr_{0.95}Eu_{0.05}BNO.

In a fifth embodiment, there is provided an oxynitride phosphor having the formula: M_{0.755-x}Lnₓ(Al,Ga)_{1.71}(Si,Ge)_{2.29}O₈₋ₓNₓ:Ce³⁺,Eu³⁺,Bi³⁺,Tb³⁺,Eu²⁺,Mn²⁺, where 0≦x≦0.755; M_{0.755-x}(Al,Ga)_{1.71-x}(Si,Ge)_{2.29+x}O₈₋ₓNₓ:Ce³⁺,Eu³⁺,Bi³⁺,Tb³⁺,Eu²⁺,Mn³⁺ where 0≦x≦1.71; M₁₋ₓLnₓ(Al,Ga)₂(Si,Ge)₂O₈₋ₓNₓ:Ce³⁺,Eu³⁺,Bi³⁺,Tb³⁺,Eu²⁺,Mn³⁺, where 0≦x≦1; or M(Al,Ga)₂₋ₓ(Si,Ge)₂₊ₓO₈₋ₓNₓ:Ce³⁺,Eu³⁺,Bi³⁺,Tb³⁺,Eu²⁺,Mn²⁺, where 0≦x≦2, and wherein for any of the preceding M is at least one of Mg, Ca, Ba, or Zn and Ln is at least one of La, Y, Gd, Lu, Pr, Nd or Sm. Phosphors prepared with AlF₃ flux will have a celsian type crystal structure.

Phosphors in this last embodiment show significantly different emission characteristics based on their composition and whether flux is used during their production. Based on this property, it is possible to spectrally tune the phosphors depending on structure and synthesis.

Specifically, the inclusion of N in the phosphor (i.e. oxynitride as opposed to oxide) results in a red shift of approximately 45 nm compared to the comparable oxide phosphor, indicative of the spectral tunability of the phosphor. When 10% Al was used in the form of AlF₃ (with the balance oxide) in the phosphor synthesis, the celsian phase was produced, which showed a lesser red shift for the oxynitride. By suitably modifying the composition of the phosphor, along with the use or omission of flux, it is possible to spectrally tune the phosphor emission.

While suitable in many applications alone with a blue or UV LED chip, the above described oxynitride phosphors may be blended with each other or one or more additional phosphors for use in LED light sources. Thus, in another embodiment, an LED lighting assembly is provided including a phosphor composition comprising a blend of a phosphor from one of the above embodiments with one or more additional phosphors. These phosphors can be used either individually for single color lamps (e.g. in traffic signal applications) or in blends with other phosphors to generate white light for general illumination. These phosphors can be blended with suitable phosphors to produce a white light emitting device with CCTs ranging from 2500 to 10,000 K and CRIs ranging from 50-99.

Non-limiting examples of suitable phosphors for use with the present inventive phosphors in phosphor blends are listed below. The specific amounts of the individual phosphors used in the phosphor blend will depend upon the desired color temperature. The relative amounts of each phosphor in the phosphor blend can be described in terms of spectral weight. The spectral weight is the relative amount that each phosphor contributes to the overall emission spectrum of the device. The spectral weight amounts of all the individual phosphors and any residual bleed from the LED source should add up to 100%. In a preferred embodiment, each of the above described phosphors in the blend will have a spectral weight ranging from about 1 to 75%.

Non-limiting examples of suitable phosphors that may be used in combination with the present oxonitridosilicate phosphors include:
(Ba,Sr,Ca)₅(PO₄)₃(Cl,F,Br, OH):Sb³⁺,Mn²⁺(Ba,Sr,Ca)MgAl₁₀O₁₇:Eu²⁺,Mn²⁺ (BAMn)
(Ba,Sr,Ca)BPO₅:Eu²⁺,Mn²⁺
(Sr,Ca)₁₀(PO₄)₆*nB₂O₃:Eu²⁺
Sr₂Si₃O₈*2SrCl₂:Eu²⁺
Ba₃MgSi₂O₈:Eu²⁺
BaAl₈O₁₃:Eu²⁺
2SrO*0.84P₂O₅*0.16B₂O₃:Eu²⁺;
(Ba,Sr,Ca)Al₂O₄:Eu²⁺
(Y,Gd,Lu,Sc,La)BO₃:Ce³⁺,Tb³⁺
Ca₈Mg(SiO₄)₄Cl₂:Eu²⁺,Mn²⁺
(Ba,Sr,Ca)₂SiO₄:Eu²⁺
(Ba,Sr,Ca)₂(Mg,Zn)Si₂O₇:Eu²⁺
(Sr,Ca,Ba)(Al,Ga,In)₂S₄:Eu²⁺
(Y,Gd,Tb,La,Sm,Pr,Lu)₃(Al,Ga)₅O₁₂:Ce³⁺
(Ca,Sr)₈(Mg,Zn)(SiO₄)₄Cl₂:Eu²⁺,Mn²⁺ (CASI)
Na₂Gd₂B₂O₇:Ce³⁺,Tb³⁺
(Ba,Sr)₂(Ca,Mg,Zn)B₂O₆:K,Ce,Tb
(Sr,Ca,Ba,Mg,Zn)₂P₂O₇:Eu²⁺,Mn²⁺ (SPP);
(Ca,Sr,Ba,Mg, Zn)₁₀(PO₄)₆(F,Cl,Br,OH):Eu²⁺,Mn²⁺ (HALO);
(Gd,Y,Lu,La)₂O₃:Eu³⁺,Bi³⁺
(Gd,Y,Lu,La)₂O₂S:Eu³⁺,Bi³⁺
(Gd,Y,Lu,La)VO₄:Eu³⁺,Bi³⁺
(Ca,Sr)S:Eu²⁺
SrY₂S₄:Eu²⁺
CaLa₂S₄:Ce³⁺
(Ca,Sr)S:Eu²⁺
(Ba,Sr,Ca)MgP₂O₇:Eu²⁺,Mn²⁺
(Y,Lu)₂WO₆:Eu³⁺,Mo⁶⁺
(Ba,Sr,Ca)ₓSi_{y}N_{z}:Eu²⁺

As stated, the inventive phosphors can be used either alone to make single color light sources or in blends for white light sources. In one preferred embodiment, the phosphor composition is a blend of one or more oxynitride phosphors and one or more gap filling phosphors, such that the light emitted from the LED device is a white light.

When the phosphor composition includes a blend of two or more phosphors, the ratio of each of the individual phosphors in the phosphor blend may vary depending on the characteristics of the desired light output. The relative proportions of the individual phosphors in the various embodiment phosphor blends may be adjusted such that when their emissions are blended and employed in an backlighting device, there is produced visible light of predetermined x and y values on the CIE chromaticity diagram. As stated, a white light is preferably produced. This white light may, for instance, may possess an x value in the range of about 0.30 to about 0.55, and a y value in the range of about 0.30 to about 0.55. As stated, however, the exact identity and amounts of each phosphor in the phosphor composition can be varied according to the needs of the end user.

The above described phosphor compositions may be produced using known solution or solid state reaction processes for the production of phosphors by combining, for example, elemental oxides, carbonates and/or hydroxides as starting materials. Other starting materials may include nitrates, sulfates, acetates, citrates, or oxalates. Alternately, coprecipitates of the rare earth oxides could be used as the starting materials for the RE elements. In a typical process, the starting materials are combined via a dry or wet blending process and fired in air or under a reducing atmosphere or in ammonia at from, e.g., 1000 to 1600° C.

A process for the production of various orthonitrodosilicates is described by Orth, et al. (Chem. Eur. J. 2001, 7, No. 13, pp. 2791-2797). This paper describes the production of compounds having the formula Ba₄RE₇[Si₁₂N₂₃O][BN₃] where RE is Pr, Nd, or Sm. This process can easily be modified to form various of the above described embodiment phosphor compositions by adding appropriate amounts of rare earth dopants in the forms of oxides, carbonates, oxalates, etc.

Specifically, the phosphors A₄₋ₓRE₇[Si₁₂N₂₃O][BN₃]:Euₓ, where A and RE are defined above, may be prepared by reaction of the appropriate RE and A (in suitable form, e.g. carbonates, oxalates or oxides), Si(NH)₂, poly-(boron amide imide) (or nitrides such as Si₃N₄ or BN) as well as the appropriate rare earth dopant(s) in nitrogen atmosphere in tungsten crucibles using a furnace with reducing atmosphere capability at temperatures up to 1650° C. The phosphor materials may subsequently be recovered and purified.

Similarly, in one method for producing the above described La₃Si₈N₁₁O₄ phosphor, stoichiometric amounts of LaN, La₂O₃, Si₃N₄, and SiO₂ may be mixed and fired together according to the equation:
LaN+La₂O₃+2.5Si₃N₄+0.5SiO₂→La₃Si₈N₁₁O₄

LaN is moisture sensitive, so it is possible to start with LaSi₃N₅, which is prepared by carbothermal reduction and nitridation using La₂O₃/SiO₂/C in a N₂ atmosphere:
LaSi₃N₅+La₂O₃ +1.5Si₃N₄+0.5SiO₂→La₃Si₈N₁₁O₄

Alternately, the above phosphor could be prepared using nanosized La—Si hydroxy powders by either coprecipitation or sol-gel (described below) and nitridation in NH₃:
1.5La₂O₃8SiO₂xH₂O+11NH₃→La₃Si₈N₁₁O₄+16.5H₂O

Other exemplary starting materials may include, for example, elemental, hydroxides, nitrates, sulfates, acetates, or citrates. In a typical process, the starting materials are combined via a dry or wet blending process and fired in air or under a reducing atmosphere at from, e.g., 900 to 1600° C.

With regard to the fifth embodiment phosphors, the above compositions Sr_{10.79}Eu_{0.21}Si₉Al₃N₁₃O₁₁[BN₃], Ba₄Sr_{6.79}Eu_{0.21}Si₉Al₃N₁₃O₁₁BN₃] and Sr_{0.095}Eu_{0.05}BNO may be prepared by the solid state reaction of BaCO₃, SrCO₃, Si₃N₄, AlN, BN, and Eu₂O₃ at 1500° C. in 1% H₂.

The amounts of each ingredient that may be used in the production of these three phosphors are listed below.

Sr_{10.79}Eu_{0.21}Si₉Al₃O₁₁[BN₃]

| | Amount for |
|---|---|
| Material | 0.01 mol (g) |
| SrCO₃ | 4.779 |
| Eu₂O₃ | 0.111 |
| Si₃N₄ | 1.263 |
| AlN | 0.369 |
| BN | 0.075 |

TBa₄Sr_{6.79}Eu_{0.21}Si₉Al₃0₁₁[BN₃]

| | Amount for |
|---|---|
| Matl | 0.01 mol (g) |
| SrCO₃ | 3.007 |
| Eu₂O₃ | 0.111 |
| Si₃N₄ | 1.263 |
| AlN | 0.369 |
| BN | 0.075 |
| BaCO₃ | 2.368 |

Sr_{0.95}Eu_{0.05}BNO

| | Amount for |
|---|---|
| Matl | 0.01 mol (g) |
| SrCO₃ | 5.470 |
| Eu₂O₃ | 0.343 |
| BN | 0.968 |

A fluxing agent may be added to the mixture before or during the step of mixing. This fluxing agent may be AlF₃, NH₄Cl or any other conventional fluxing agent, such as a fluoride of at least one metal selected from the group consisting of terbium, aluminum, gallium, and indium. A quantity of a fluxing agent of less than about 20, preferably less than about 10, percent by weight of the total weight of the mixture is exemplary for fluxing purposes.

The starting materials may be mixed together by any mechanical method including, but not limited to, stirring or blending in a high-speed blender or a ribbon blender. The starting materials may be combined and pulverized together in a bowl mill, a hammer mill, or a jet mill. The mixing may be carried out by wet milling especially when the mixture of the starting materials is to be made into a solution for subsequent precipitation. If the mixture is wet, it may be dried first before being fired under a reducing atmosphere at a temperature from about 900° C. to about 1700° C., preferably from about 1500° C. to about 1600° C., for a time sufficient to convert all of the mixture to the final composition.

The firing may be conducted in a batchwise or continuous process, preferably with a stirring or mixing action to promote good gas-solid contact. The firing time depends on the quantity of the mixture to be fired, the rate of gas conducted through the firing equipment, and the quality of the gas-solid contact in the firing equipment. Typically, a firing time up to about 10 hours is adequate but for phase formation it is desirable to refire couple of times at the desired temperatures after grinding. The reducing atmosphere typically comprises a reducing gas such as hydrogen, carbon monoxide, ammonia or a combination thereof, optionally diluted with an inert gas, such as nitrogen, helium, etc., or a combination thereof. Alternatively, the crucible containing the mixture may be packed in a second closed crucible containing high-purity carbon particles and fired in air so that the carbon particles react with the oxygen present in air, thereby, generating carbon monoxide for providing a reducing atmosphere.

These compounds may be blended and dissolved in a nitric acid solution. The strength of the acid solution is chosen to rapidly dissolve the oxygen-containing compounds and the choice is within the skill of a person skilled in the art. Ammonium hydroxide is then added in increments to the acidic solution. An organic base such as methylamine, ethylamine, propylamine, dimethylamine, diethylamine, dipropylamine, trimethylamine, triethylamine, or the like may be used in place of ammonium hydroxide.

The precipitate is typically filtered, washed with deionized water, and dried. The dried precipitate is ball milled or otherwise thoroughly blended and then calcined in air at about 400° C. to about 1600° C. for a sufficient time to ensure a substantially complete dehydration of the starting material. The calcination may be carried out at a constant temperature. Alternatively, the calcination temperature may be ramped from ambient to and held at the final temperature for the duration of the calcination. The calcined material is similarly fired at 1000-1600° C. for a sufficient time under a reducing atmosphere such as H₂, CO, or a mixture of one of theses gases with an inert gas, or an atmosphere generated by a reaction between a coconut charcoal and the products of the decomposition of the starting materials or using ammonia gas to covert all of the calcined material to the desired phosphor composition.

Alternatively, a sol-gel synthesis may also be used to produce the phosphors of the present invention. Thus, in an exemplary process, a phosphor for use in the present invention can be made by first combining predetermined amounts of appropriate oxide compounds and wetting them with water. Dilute nitric acid is then added to dissolve the oxide and carbonates. The solution is then dried to remove excess nitric acid and then dissolved in absolute ethanol. In a second container, a predetermined amount of tetraethyl orthosilicate (TEOS) is dissolved in absolute ethanol. The contents of the two containers are then combined and stirred under heat until gelling occurs. The gel is subsequently heated in an oven to remove organics, ground to a powder, and then calcined at 800-1200° C. Finally, the powder may be ground again and further calcined in 1% H₂ reducing atmosphere at 1400° C. for 5 hours. Calcination in ammonia gas is desirble for the formation of the desired phase especially when using all oxide/hydroxide precursors. Similar procedures can be used for the other described phosphors.

It may be desirable to add pigments or filters to the phosphor material. The phosphor layer 22 may also comprises from 0 up to about 5% by weight (based on the total weight of the phosphors) of a pigment or other UV absorbent material capable of absorbing UV radiation having a wavelength between 250 nm and 450 nm.

Suitable pigments or filters include any of those known in the art that are capable of absorbing radiation generated between 250 nm and 450 nm. Such pigments include, for example, nickel titanate or praseodimium zirconate. The pigment is used in an amount effective to filter 10% to 100% of the radiation generated in the 250 nm to 450 nm range.

### EXAMPLES

Specific exemplary phosphors were created. The amount of each component necessary to form the phosphors are listed below. The values given in the following tables reflect the loss on ignition (LOI) which was taken into account for SiO₂ (used as silicic acid) and the cerium carbonate (used as a hydrate).

(Lu_{0.97}Ce_{0.03})₄Si₂N₂O₇

| | Amount (g) |
|---|---|
| Lu₂O₃ | 6.948 |
| Ce₂(CO₃)₃ | 0.248 |
| Si₃N₄ | 0.631 |
| SiO₂ | 0.270 |

In other trials, phosphors according to the fifth embodiment were synthesized. The amount of each component necessary to form the phosphors are listed below:

Ba_{0.7}Al_{1.71}Si_{2.29}O₈:Eu_{0.1}

| | Amount (g) |
|---|---|
| BaCO₃ | 2.763 |
| Eu₂O₃ | 0.352 |
| Al₂O₃ | 1.733 |
| SiO₂ | 2.752 |

Ca_{0.7}Al_{1.21}Si_{2.79}O_{7.5}N_{0.5}:Mn_{0.1}, Eu_{0.1}

| | Amount (g) |
|---|---|
| CaCO₃ | 1.401 |
| Eu₂O₃ | 0.352 |
| Al₂O₃ | 0.724 |
| AlN | 0.409 |
| SiO₂v | 3.353 |
| MnCO₃ | 0.230 |

Ba_{0.7}Al_{1.21}Si_{2.79}O_{7.5}N_{0.5}:Eu_{0.1}

| | Amount (g) |
|---|---|
| BaCO₃ | 2.763 |
| Eu₂O₃ | 0.352 |
| Al₂O₃ | 0.724 |
| AlN | 0.410 |
| SiO₂ | 3.353 |

By assigning appropriate spectral weights for each phosphor, we can create spectral blends to cover the relevant portions of color space, especially for white lamps. For various desired CCT's, CRI's and color points, one can determine the appropriate amounts of each phosphor to include in the blend. Thus, one can customize phosphor blends to produce almost any CCT or color point, with corresponding high CRI. Of course, the color of each phosphor will be dependent upon its exact composition. However, determining the changes in the spectral weight to produce the same or similar characteristic lighting device necessitated by such variations is trivial and can be accomplished by one skilled in the art using various methodologies, such as design of experiment (DOE) or other strategies.

By use of the present invention, particularly the blends described in embodiment two, lamps can be provided having CRI values greater than 90, over the entire range of color temperatures of interest for general illumination (2500 K to 8000 K). In some blends, the CRI values may approach the theoretical maximum of 100.

The phosphor composition described above may be used in additional applications besides LEDs. For example, the material may be used as a phosphor in a fluorescent lamp, mercury or metal halide lamps, in a cathode ray tube, in a plasma display device or in a liquid crystal display (LCD). The material may also be used as a scintillator in an electromagnetic calorimeter, in a gamma ray camera, in a computed tomography scanner or in a laser. These uses are meant to be merely exemplary and not exhaustive.

The exemplary embodiment has been described with reference to the preferred embodiments. Obviously, modifications and alterations will occur to others upon reading and understanding the preceding detailed description. It is intended that the exemplary embodiment be construed as including all such modifications and alterations insofar as they come within the scope of the appended claims or the equivalents thereof.

What is claimed is:

1. A lighting apparatus for emitting white light comprising:
a light source emitting with a peak radiation at from about 250 nm to about 550 nm and a phosphor material radiationally coupled to the light source, the phosphor material comprising at least one of:
a) M₄₊ₓLn₇₋ₓ(Si,Ge)_{12-y}(Al,Ga)_{y}N_{23-x-y}O_{1+x+y}[BN₃:Ce³⁺,Eu³⁺,Bi³⁺,Tb³⁺,Eu²⁺,Mn²⁺ where 0≦x≦7, 0≦y≦12; M is at least one of Mg, Ca, Sr, Ba, or Zn and Ln is at least one of the rare earth elements, Sc, Y, Bi, or Sb;
b) Ln₃₋ₓMₓ(Si,Ge)₈N₁₁₋ₓO₄₊ₓ:RE; Ln₃(Si,Ge)₈₋ₓ(Al,Ga)ₓN₁₁₋ₓO₄₋ₓ:RE; or Ln₃₋ₓMₓ(Si,Ge)₈₋ₓAlₓN_{11-x/2}O_{4-x/4}:RE where Ln is at least one of Lu, Y, La, Gd, or Sc, M is at least one of Ca, Sr, Ba or Zn, 0≦x≦3, and RE is at least one of Ce³⁺, Tb³⁺, Pr³⁺, Dy³⁺, Sm³⁺, Eu³⁺, Eu²⁺, Mn²⁺, or Bi³⁺;
c) Ln₄Si₂O₇N₂:RE where Ln is at least one of Lu, Y, La, Gd, or Sc and RE is at least one of Ce³⁺, Tb³⁺, Pr³⁺, Dy³⁺, Eu³⁺, Sm³⁺, Eu³⁺, Eu²⁺, Mn²⁺, or Bi³⁺;
d) Ln₄₋ₓMₓ(Si,Ge)₂N₂₋ₓO₇₊ₓ or Ln₄₋ₓMₓ(Si,Ge)_{2-y}(Al,Ga)_{y}N_{2-x-y}O_{7+x+y}:RE where Ln is at least one of Lu, Y, La, Gd, or Sc, M is at least one of Ca, Sr, Ba, or Zn, 0≦x≦2, 0≦y≦2, and RE is at least one of Ce³⁺, Tb³⁺, Pr³⁺, Dy³⁺, Sm³⁺, Eu³⁺, Eu²⁺, Mn²⁺, or Bi³⁺;
e) MBNO:Eu²⁺,Mn²⁺ where M is at least one of Mg, Ca, Ba, Sr, or Zn; or
f) M_{0.755}Lnₓ(Al,Ga)_{1.71}(Si,Ge)_{2.29}O₈₋ₓNₓ:Ce³⁺,Eu³⁺,Bi³⁺,Tb³⁺,Eu²⁺,Mn²⁺, where 0≦x≦0.755; M_{0.755}(Al,Ga)_{1.71-x}(Si,Ge)_{2.29+x}O₈₋ₓNₓ:Ce³⁺,Eu³⁺,Bi³⁺,Tb³⁺,Eu²⁺,Mn²⁺ where 0≦x≦1.71; M₁₋ₓLnₓ(Al,Ga)₂(Si,Ge)₂O₈₋ₓNₓ:Ce³⁺,Eu³⁺,Bi³⁺,Tb³⁺,Eu²⁺,Mn²⁺, where 0≦x≦1; or M(Al,Ga)₂₋ₓ(Si,Ge)₂₊ₓO₈₋ₓNₓ:Ce³⁺,Eu³⁺,Bi³⁺, Tb³⁺,Eu²⁺,Mn²⁺, where 0≦x≦2, and wherein for any of the preceding M is at least one of Mg, Ca, Ba, or Zn and Ln is at least one of La, Y, Gd, Lu, Pr, Nd or Sm.

2. The lighting apparatus of claim 1, wherein the light source comprises one of an LED and an organic emissive structure.

3. The lighting apparatus of claim 1, further comprising an encapsulant surrounding the light source.

4. The lighting apparatus of claim 3, wherein the phosphor material is dispersed in the encapsulant.

5. The lighting apparatus of claim 1, further comprising a reflector cup.

6. The lighting apparatus according to claim 1, wherein the phosphor material is coated on a surface of the light source.

7. The lighting apparatus according to claim 1, wherein the phosphor material comprises at least one member of the group including: (Lu_{0.97}Ce_{0.03})₄Si₂N₂O₇; (Lu_{0.985}Ce_{0.015})₈Si₃AlN₅O₁₂; (Lu_{0.985}Ce_{0.015})₇Si₃AlN₄O₁₃; (Lu_{0.985}Ce_{0.015})₆Ca₂Si₃AlN₅O₁₁; (Lu_{0.95}Ce_{0.05})₈Si₃AlN₅O₁₂; (Lu_{0.97}Ce_{0.03})₄Si₄N₄O₁₃; (Lu_{0.97}Ce_{0.03})₄Si₃AlN₅O₆; (Lu_{0.97}Ce_{0.03})₆Si₃N₄O₉; (Lu_{0.97}Ce_{0.03})₆Si₃N₄O₉; and (Lu_{0.985}Ce_{0.015})₇Si₃AlN₅O_{11.5}.

8. The lighting apparatus of claim 1, further including a pigment, filter or other absorber capable of absorbing radiation generated between 250 nm and 450 nm.

9. The lighting apparatus of claim 1, further comprising one or more additional phosphors selected from the group consisting of (Ba,Sr,Ca)₅(PO₄)₃(Cl,F,Br, OH):Sb³⁺,Mn²⁺; (Ba,Sr,Ca)MgAl₁₀O₁₇:Eu²⁺,Mn²⁺; (Ba,Sr,Ca)BPO₅:Eu²⁺,Mn²⁺; (Sr,Ca)₁₀(PO₄)₆*nB₂O₃:Eu²⁺;Sr₂Si₃O₈*2SrCl₂:Eu²⁺; Ba₃MgSi₂O₈:BaAl₈O₁₃:Eu²⁺; 2SrO*0.84P₂O₅*0.16B₂O₃:Eu²⁺; (Ba,Sr,Ca)Al₂O₄:Eu²⁺; (Y,Gd,Lu,Sc,La)BO₃:Ce³⁺,Tb³⁺; Ca₈Mg(SiO₄)₄Cl₂:Eu²⁺,Mn²⁺; (Ba,Sr,Ca)₂SiO₄:Eu²⁺; (Ba,Sr,Ca)₂(Mg,Zn)Si₂O₇:Eu²⁺; (Sr,Ca,Ba)(Al,Ga,In)₂S₄:Eu²⁺; (Y,Gd,Tb,La,Sm,Pr, Lu)₃(Al,Ga)₅_{O}₁₂:Ce³⁺; (Ca,Sr)₈(Mg,Zn)(SiO₄)₄Cl₂:Eu²⁺,Mn²⁺; Na₂Gd₂B₂_{O}₇:Ce³⁺, Tb³⁺; (Ba,Sr)₂(Ca,Mg,Zn)B₂O₆:K,Ce,Tb; (Sr,Ca,Ba,Mg,Zn)₂P₂O₇:Eu²⁺,Mn²⁺; (Ca,Sr,Ba,Mg, Zn)₁₀(PO₄)₆(F,Cl,Br,OH):Eu²⁺,Mn²⁺; (Gd,Y,Lu,La)₂O₃:Eu³⁺,Bi³⁺; (Gd,Y,Lu,La)₂O₂S:Eu³⁺,Bi³⁺; (Gd,Y,Lu,La)VO₄:Eu³⁺,Bi³⁺; (Ca,Sr)S:Eu²⁺; SrY₂S₄:Eu²⁺; CaLa₂S₄:Ce³⁺; (Ca,Sr)S:Eu²⁺; (Ba,Sr,Ca)MgP₂O₇:Eu²⁺,Mn²⁺; (Y,Lu)₂WO₆:Eu³⁺,Mo⁶⁺; (Ba,Sr,Ca)ₓSi_{y}N_{z}:Eu²⁺; and blends thereof.

10. A phosphor composition comprising:
a) M₄₊ₓLn₇₋ₓ(Si,Ge),₁₂₋ₓY(Al,Ga)_{y}N_{23-x-y}O_{1+x+y}[BN₃]:Ce³⁺,Eu³⁺,Bi³⁺,Tb³⁺,Eu²⁺,Mn²⁺ where 0≦x≦7, 0≦y≦12; M is at least one of Mg, Ca, Sr, Ba, or Zn and Ln is at least one of the rare earth elements, Sc, Y, Bi, or Sb;
b) Ln₃₋ₓMₓ(Si,Ge)₈N₁₁₋ₓO₄₊ₓ:RE; Ln₃(Si,Ge)₈₋ₓ(Al,Ga)ₓN₁₁₋ₓO₄₊ₓ:RE; or Ln₃₋ₓMₓ(Si,Ge)₈₋ₓAlₓN_{11-x/2}:RE where Ln is at least one of Lu, Y, La, Gd, or Sc, M is at least one of Ca, Sr, Ba or Zn, 0≦x≦3, and RE is at least one of Ce³⁺, Tb³⁺, Pr³⁺, Dy³⁺, Sm³⁺, Eu³⁺, Eu²⁺, Mn²⁺, or Bi³⁺;
c) Ln₄Si₂O₇N₂:RE where Ln is at least one of Lu, Y, La, Gd, or Sc and RE is at least one of Ce³⁺, Tb³⁺, Pr³⁺, Dy³⁺, Eu³⁺, Sm³⁺, Eu³⁺, Eu²⁺, Mn²⁺, or Bi³⁺;
d) Ln₄Mₓ(Si,Ge)₂N₂₋ₓO₇₊ₓ or Ln₄₋ₓMₓ(Si,Ge)_{2-y}(Al,Ga)_{y}N_{2-x-y}O_{7+x+y}:RE where Ln is at least one of Lu, Y, La, Gd, or Sc, M is at least one of Ca, Sr, Ba, or Zn, 0≦x≦2, 0≦y≦2, and RE is at least one of Ce³⁺, Tb³⁺, Pr³⁺, Dy³⁺, Sm³⁺, Eu³⁺, Eu²⁺, Mn²⁺, or Bi³⁺;
e) MBNO:Eu²⁺, Mn²⁺ where M is at least one of Mg, Ca, Ba, Sr, or Zn; or
f) M_{0.755-x}Lnₓ(Al,Ga)_{1.71}(Si,Ge)_{2.29}O₈₋ₓNₓ:Ce³⁺,Eu³⁺,Bi³⁺,Tb³⁺,Eu²⁺,Mn²⁺, where 0≦x≦0.755; M_{0.755}(Al,Ga)_{1.71-x}(Si,Ge)_{2.29+x}O₈₋ₓNₓ:Ce³⁺,Eu³⁺,Bi³⁺,Tb³⁺,Eu²⁺,Mn²⁺ where 0≦x≦1.71; M₁₋ₓLnₓ(Al,Ga)₂(Si,Ge)₂O₈₋ₓNₓ:Ce³⁺,Eu³⁺, Bi³⁺,Tb³⁺,Eu²⁺,Mn²⁺, where 0≦x≦1; or M(Al,Ga)₂₋ₓ(Si,Ge)₂₊ₓO₈₋ₓNₓ:Ce³⁺,Eu³⁺,Bi³⁺,Tb³⁺,Eu²⁺,Mn²⁺, where 0≦x≦2, and wherein for any of the preceding M is at least one of Mg, Ca, Ba, or Zn and Ln is at least one of La, Y, Gd, Lu, Pr, Nd or Sm.

11. The phosphor composition according to claim 10, wherein said phosphor composition is capable of absorbing the radiation emitted by a light source emitting from 250-550 nm and emitting radiation that, when combined with said radiation from said light source, produces white light.

12. The phosphor composition according to claim 10, wherein said phosphor composition is selected from the group including: (Lu_{0.97}Ce_{0.03})₄Si₂N₂O₇; (Lu_{0.985}Ce_{0.015})₈Si₃AlN₅O₁₂; (Lu_{0.985}Ce_{0.015})₇Si₃AlN₄O₁₃; (Lu_{0.985}Ce_{0.015})₆Ca₂Si₃AlN₅O₁₁; (Lu_{0.95}Ce_{0.05})₈Si₃AlN₅O₁₂; (Lu_{0.97}Ce_{0.03})₄Si₄N₄O₈; (Lu_{0.97}Ce_{0.03})₄Si₃AlN₅O₆; (Lu_{0.97}Ce_{0.03})₆Si₃N₄O₉; (Lu_{0.97}Ce_{0.03})₆Si₃N₄O₉; and (Lu_{0.0985}Ce_{0.015})₇CaSi₃AlN₅O_{11.5}.

13. A phosphor blend including a first phosphor comprising:
a) M₄₊ₓLn₇₋ₓ)(Si,Ge)_{12-y}(Al,Ga)_{y}N_{23-x-y}O_{1+x+y}[BN₃]:Ce³⁺,Eu³⁺,Bi³⁺,Tb^{3°},Eu²⁺,Mn²⁺ where 0≦x≦7, 0≦y≦12; M is at least one of Mg, Ca, Sr, at least one of the rare earth elements, Sc, Y, Bi, or Sb;
b) Ln₃₋ₓMₓ(Si,Ge)₈N₁₁₋ₓO₄₊:RE; Ln₃(Si,Ge)₈₋ₓ(Al,Ga)ₓN₁₁₋ₓO₄₊ₓ:RE; or Ln₃₋ₓMₓ(Si,Ge)₈₋ₓAlₓN_{11-x/2}O_{4-x/4}:RE where Ln is at least one of Lu, Y, La, Gd, or Sc, M is at least one of Ca, Sr, Ba or Zn, 0≦x≦3, and RE is at least one of Ce³⁺, Tb³⁺, Pr³⁺, Dy³⁺, Sm³⁺, Eu³⁺, Eu²⁺, Mn²⁺, or Bi³⁺;
c) Ln₄Si₂O₇N₂:RE where Ln is at least one of Lu, Y, La, Gd, or Sc and RE is at least one of Ce³⁺, Tb³⁺, Pr³⁺, Dy³⁺, Eu³⁺, Sm³⁺, Eu³⁺, Eu²⁺, Mn²⁺, or Bi³⁺;
d) Ln₄₋ₓMₓ(Si,Ge)₂N₂₋ₓO₇₊ₓ or Ln₄₋ₓMₓ(Si,Ge)_{2-y}(Al,Ga)_{y}N_{2-x-y}O_{7+x+y}:RE where Ln is at least one of Lu, Y, La, Gd, or Sc, M is at least one of Ca, Sr, Ba, or Zn, 0≦x≦2, 0≦y≦2, and RE is at least one of Ce³⁺, Tb³⁺, Pr3+, Dy³⁺, Sm³⁺, Eu³⁺, Eu²⁺, Mn²⁺, or Bi³⁺;
e) MBNO:Eu²⁺,Mn²⁺ where M is at least one of Mg, Ca, Ba, Sr, or Zn; or
f) M_{0.755-x}Lnₓ(Al,Ga)_{1.71}(Si,Ge)_{2.29}O₈₋ₓNₓ:Ce³⁺,Eu³⁺,Bi³⁺,Tb³⁺,Eu²⁺,Mn²⁺, where 0≦x≦0.755; M_{0.755}(Al,Ga)_{1.71-x}(Si,Ge)_{2.29+x}O₈₋ₓNₓ:Ce³⁺,Eu²⁺,Mn²⁺ where 0≦x≦1.71; M₁₋ₓLnₓ(Al,Ga)₂(Si,Ge)₂O₈₋ₓNₓ:Ce³⁺,Eu³⁺,Bi³⁺,Tb³⁺,Eu²⁺,Mn²⁺, where 0≦x≦1; or M(Al,Ga)₂₋ₓ(Si,Ge)₂₊ₓO₈₋ₓNₓ:Ce³⁺,Eu³⁺,Bi³⁺,Tb³⁺,Eu²⁺,Mn²⁺, where 0≦x≦2, and wherein for any of the preceding M is at least one of Mg, Ca, Ba, or Zn and Ln is at least one of La, Y, Gd, Lu, Pr, Nd or Sm.

14. The phosphor blend of claim 13, further comprising one or more additional phosphors selected from the group consisting of (Ba,Sr,Ca)₅(PO₄)₃(Cl,F,Br,OH):Sb³⁺,Mn²⁺; (Ba,Sr,Ca)MgAl₁₀O₁₇:Eu²⁺,Mn²⁺; (Ba,Sr,Ca)BPO₅:Eu²⁺,Mn²⁺; (Sr,Ca)₁₀(PO₄)₆*nB₂O₃:Eu²⁺; Sr₂Si₃O₈*2SrCl₂:Eu²⁺; Ba₃MgSi₂O₈:Eu²⁺; BaAl₈O₁₃:Eu²⁺; 2SrO*0.84P₂O₅*0.16B₂O₃:Eu²⁺; (Ba,Sr,Ca)Al₂O₄:Eu²⁺; (Y,Gd,Lu,Sc,La)BO₃:Ce³⁺,Tb³⁺; Ca₈Mg(SiO₄)₄Cl₂:Eu²⁺,Mn²⁺; (Ba,Sr,Ca)₂SiO₄:Eu²⁺; (Ba,Sr,Ca)₂(Mg,Zn)Si₂O₇:Eu²⁺; (Sr,Ca,Ba)(Al,Ga,In)₂S₄:Eu²⁺; (Y,Gd,Tb,La,Sm,Pr,Lu)₃(Al,Ga)₅O₁₂:Ce³⁺; (Ca,Sr)₈(Mg,Zn)(SiO₄)₄Cl₂:Eu²⁺,Mn²⁺; Na₂Gd₂B₂O₇:Ce³⁺,Tb³⁺; (Ba,Sr)₂(Ca,Mg,Zn)B₂O₆:K,Ce,Tb; (Sr,Ca,Ba,Mg,Zn)₂P₂O₇:Eu²⁺,Mn²⁺;(Ca,Sr,Ba,Mg, Zn)₁₀(PO₄)₆(F,Cl,Br,OH):Eu²⁺,Mn²⁺; (Gd,Y,Lu,La)₂O₃:Eu³⁺,Bi³⁺; (Gd,Y,Lu,La)₂O₂S:Eu³⁺,Bi³⁺; (Gd,Y,Lu,La)VO₄:Eu³⁺,Bi³⁺; (Ca,Sr)S:Eu²⁺; CaLa₂S₄:Ce³⁺; (Ca,Sr)S:Eu²⁺; (Ba,Sr,Ca)MgP₂O₇:Eu²⁺,Mn²⁺; (Y,Lu)₂WO₆:Eu³⁺,Mo⁶⁺; (Ba,Sr,Ca)ₓSi_{y}N_{z}:Eu²⁺; and blends thereof.

15. The phosphor blend according to claim 13, wherein the phosphor blend comprises at least one member of the group including: (Lu_{0.97}Ce_{0.03})₄Si₂N₂O₇; (Lu_{0.985}Ce_{0.015})₈Si₃AlN₅O₁₂; (Lu_{0.985}Ce_{0.015})₇Si₃AlN₄O₁₃; (Lu_{0.985}Ce_{0.015})₆Ca₂Si₃AlN₅O₁₁; (Lu_{0.95}Ce_{0.05})₈Si₃AlN₅O₁₂; (Lu_{0.97}Ce_{0.03})₄Si₄N₄O₈; (Lu_{0.97}Ce_{0.03})₄Si₃AlN₅O₆; (Lu_{0.97}Ce_{0.03})₆Si₃N₄O₉; (Lu_{0.97}Ce_{0.03})₆Si₃N₄O₉; and (Lu_{0.985}Ce_{0.015})₇Si₃AlN₅O_{11.5}.
